(19) United States
(12) Patent Application Publication
(10) Pub. No.: US 2009/0026501 A1
(43) Pub. Date: Jan. 29, 2009

(54) ENHANCEMENT - DEPLETION SEMICONDUCTOR STRUCTURE AND METHOD FOR MAKING IT

(75) Inventors: Hassan Maher, Massy (FR); Pierre Baudet, Yerres (FR)

Correspondence Address: SCULLY SCOTT MURPHY & PRESSER, PC, 400 GARDEN CITY PLAZA, SUITE 300, GARDEN CITY, NY, 11530, US

(73) Assignee: KONINKLIJKE PHILIPS ELECTRONICS, N.V., EINDHOVEN (NL)

(21) Appl. No.: 11/722,208

(22) PCT Filed: Dec. 13, 2005
(86) PCT No.: PCT/IB05/54219

§ 371 Date: Mar. 13, 2008

(30) Foreign Application Priority Data
Dec. 30, 2004 (EP) 04300956.2

(51) Int. Cl. H01L 21/337; H01L 29/778

(52) U.S. Cl. 257/195; 438/172; 257/E29.246; 257/E21.445

(57) ABSTRACT

A ED-HEMT structure includes a buffer layer (4) including a doped layer (18), a channel layer (6), a barrier layer (8), and a second doped layer (20). An enhancement mode HEMT gate (12) is formed in a via extending through the second doped layer (20) and a depletion mode HEMT structure is formed over the second doped layer (20). The layer sequence allows the formation of both enhancement and depletion mode HEMTs in the same structure with good properties.

The invention relates to a semiconductor structure including both enhancement and depletion mode heterostructure field effect transistors (HFET), and in particular but not exclusively to a structure including high electron mobility transistors (HEMT).

In a typical HFET, a metal gate contact forms a Schottky barrier with a Schottky barrier semiconductor layer over a channel semiconductor layer, the channel semiconductor layer forming a heterostructure with the Schottky barrier semiconductor layer. Source and drain contacts are provided on either side of the gate. The voltage on the metal gate contact controls conduction in the channel between the source and drain contacts.

Generally, such HFETs are implemented to have a high electron mobility and accordingly are known as high electron mobility transistors (HEMTs).

Such HEMTs may be implemented as enhancement mode devices, which are off unless a voltage is applied to the gate to turn the device on, or depletion mode devices which are on until a voltage is applied to the gate to turn them off. There is a need for both enhancement and depletion type FETs to be implemented using a single manufacturing process so that enhancement and depletion type FETs can be integrated together. Such integrated FETs are known as enhancement-depletion high electron mobility transistors (ED-HEMTs), which include both enhancement and depletion HEMTs.

In such ED-HEMTs, a high charge per unit area in the channel is required both to improve the intrinsic performance but also to reduce the parasitic series resistance. This is generally achieved by including a delta doped layer near the channel to provide carriers in the channel.

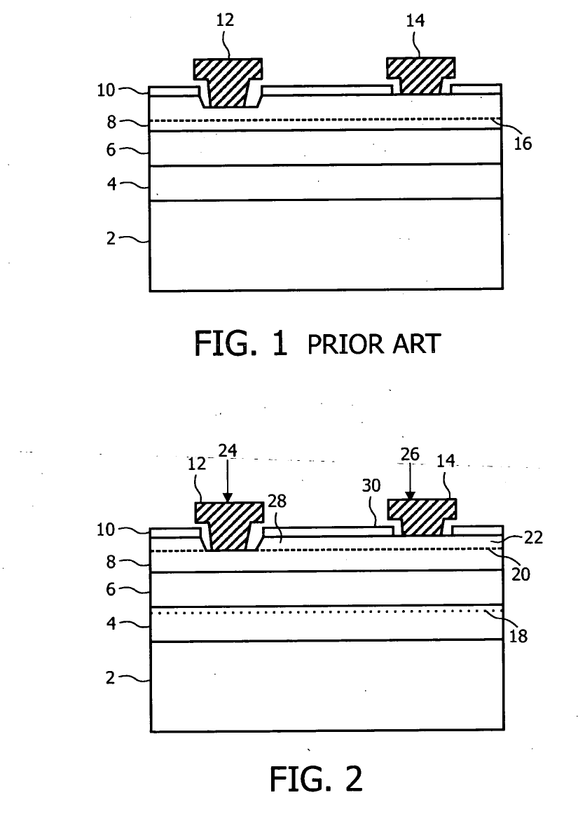

FIG. 1 illustrates such a HEMT. A substrate 2 forms the base.

A buffer layer 4 is provided on the substrate and a channel layer 6 on the buffer layer 4. A barrier layer 8 follows and a cap layer 10 is provided on top of the substrate. A delta-doped layer 16 in the barrier layer 8 provides electrons to the channel 6.

The structure can produce either an enhancement or a depletion FET simply by adjusting the gate position. For creating an enhancement FET, the cap layer 10 and the barrier layer is partially etched away to create a recess in the barrier layer and a gate electrode 12 is arranged in the recess. To create a depletion FET, the cap layer is etched away and a gate electrode 14 arranged on the top of the barrier layer 8.

Unfortunately, the high carrier density needed in the channel for good performance requires the barrier layer 8 to be very thin, typically less than 5 nm, since otherwise the channel of the enhancement HEMT cannot be pinched off at zero gate-source voltage (V_{gs}=0). The static electric field across this thin barrier can be very high, even with no gate voltage apply, which can deliver a substantial leakage current through the gate barrier reducing the maximum forward gate voltage and the gate voltage swing.

Further, the series resistance of the E-HEMTs can seriously limit device performance.

There thus remains a need for improved ED-HEMTs and corresponding methods of manufacture.

According to the invention, there is provided a semiconductor structure including at least one enhancement mode transistor and at least one depletion mode transistor, the semiconductor structure comprising:

a substrate having a first major surface;

a buffer layer of semiconductor across the first major surface;

a channel layer of semiconductor on the buffer layer;

a barrier layer of semiconductor having a second band gap higher than the first band gap on the channel layer;

a first doped layer in the buffer layer adjacent to the channel layer for providing carriers to the channel layer; and

a second doped layer above the barrier layer;

wherein the channel layer is of semiconductor having a band gap less than the band gap of the semiconductor of the buffer layer and less than the band gap of the semiconductor of the barrier layer;

the at least one enhancement mode transistor includes a gate extending through the second doped layer and in contact with the barrier layer; and

the at least one depletion mode transistor includes a gate arranged above the second doped layer.

The arrangement is able to reduce series resistance of the enhancement HEMT, and to deliver relatively good static and dynamic performances. Good output conductances and noise figures may be obtained, together with a wide gate voltage swing.

By providing electrons to the channel from the first doped layer there is no need to provide a delta-doped layer in the barrier layer very close to the channel layer, i.e. less than 5 nm. In the prior art arrangement of FIG. 1 the delta-doped layer 16 is close to the channel 6 and in general non-uniformly doped. This can easily result in leakage current paths. In the invention, this may be avoided. Accordingly, the thickness of the barrier layer between the second doped layer and the channel is preferably greater than 5 nm, further preferably greater than 10 nm.

In one approach, the second doped layer defines an opening through the second doped layer at the enhancement mode transistor and the gate of the enhancement mode transistor extends through the opening onto the barrier layer.

In another approach the gate of the enhancement mode transistor includes a gate diffusion extending through the second doped layer. The gate diffusion may be of platinum.

The gates may have a T-gate structure having a contact region in contact with second barrier layer and a region of larger lateral cross section than the contact region above the contact region.

Preferably, the first doped layer is a delta-doped layer.

The second doped layer may be a delta-doped layer. A spacer layer may be provided on the second doped layer.

A cap layer may be provided on the second doped layer, or on the spacer layer if present. The cap layer may define openings for the gates of the enhancement mode transistors and for the gates of the depletion mode transistors.

In embodiments, the channel layer is of GaInAs and the buffer and barrier layers are of AlInAs. Any other appropriate material can be used.

In another aspect, there is provided a method of manufacturing a semiconductor structure including at least one enhancement mode transistor and at least one depletion mode transistor;

providing a substrate having a first major surface;

depositing a buffer layer of semiconductor across the first major surface and forming a first doped layer in the buffer layer;

depositing a channel layer of semiconductor on the buffer layer;

depositing a barrier layer of semiconductor on- the channel layer wherein the channel layer is of semiconductor having a band gap less than the band gap of the semiconductor of the buffer layer and less than the band gap of the semiconductor of the barrier layer;

depositing a second doped layer above the barrier layer;

for the at least one enhancement mode transistor depositing a gate on the barrier layer; and

for the at least one depletion mode transistor depositing a gate on the second doped layer.

A particular benefit of the manufacturing method is that no etch stop is needed. In conventional ED-HEMTs, an etch stop is used to ensure that the etch to form the gates of the enhancement devices stops in exactly the correct place. However, using the invention, the pinch-off voltage is only weakly dependent on the thickness of the barrier layer under the enhancement gate So no etch stop layer is required, in other words the gates of the enhancement and depletion transistors may be placed at the same depth. So no special etch stop is needed for the enhancement transistor. Instead, either a gate diffusion or a gate extending through an opening to substantially the correct depth is used.

The absence of an etch stop in the Schottky layer allows a significantly improved series resistance of the E-HEMT which in turn can deliver a much better dynamic performance than conventionally achieved with this type of HEMT.

The step of forming the at least one enhancement mode transistor may includes etching a gate opening through the second doped layer and depositing the gate on the barrier layer in the opening.

The step of forming the at least one enhancement mode transistor may include depositing a first gate material on the second doped layer followed by diffusing the material of the first gate material through the second doped layer to the barrier layer.

The step of forming the gate electrodes includes depositing a diffusion gate material that diffuses through the second doped layer on the second doped layer of the enhancement mode transistor but not the depletion mode transistor;

depositing gate material on the diffusion gate material of the enhancement mode transistor and on the second doped layer of the depletion mode transistor; and

heating the structure to diffuse the diffusion gate material through the second doped layer to the barrier layer.

The diffusion gate material may be of platinum.

For a better understanding of the invention embodiments will be described, purely by way of example, with reference to the accompanying drawings in which:

FIG. 1 shows a conventional ED-HEMT structure.

FIG. 2 shows a first embodiment of an ED-HEMT structure according to the invention;

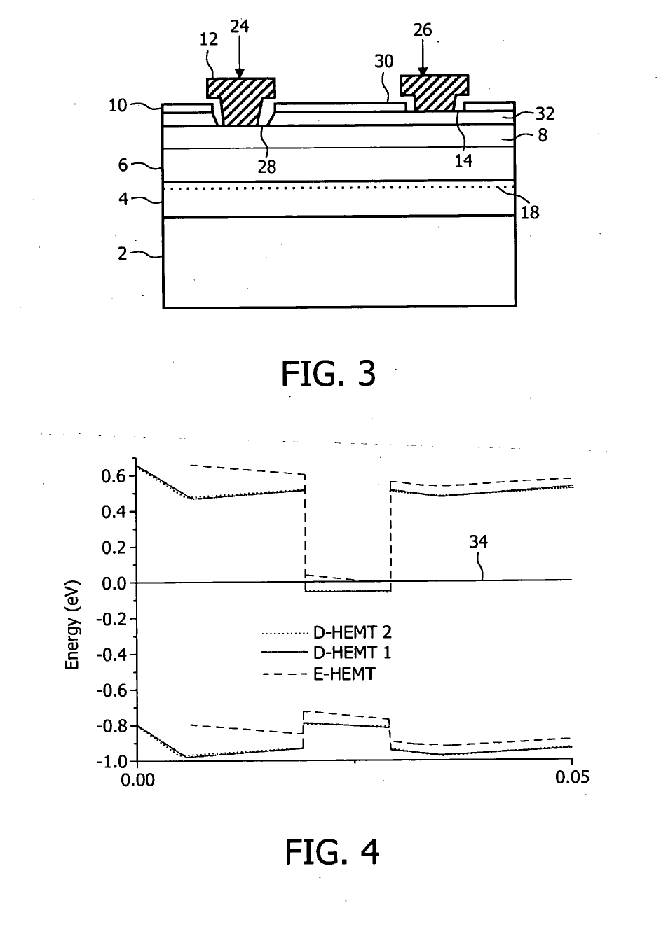

FIG. 3 shows a second embodiment of an ED-HEMT structure according to the invention;

FIG. 4 shows the band diagrams of the enhancement and depletion HEMTs of the first and second embodiments; and

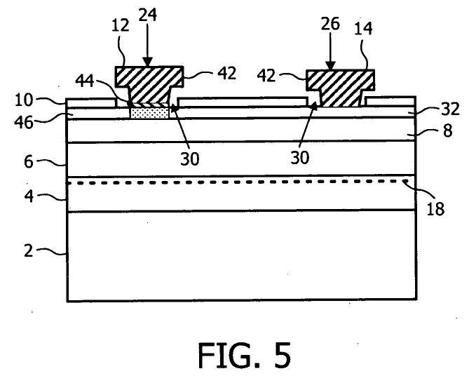

FIG. 5 shows a third embodiment of an ED-HEMT structure according to the invention.

The figures are schematic and not to scale. Like or corresponding components in the figures are given the same reference numerals.

Referring to FIG. 2, a first embodiment of the invention starts with an InP substrate 2.

An AlInAs buffer layer 4 is deposited on the substrate 2, which in the embodiment is of Al_{0.48}In_{0.52}As. The buffer layer is delta doped to provide a first delta-doped layer 18 near the top of the buffer layer. The buffer layer is 32 nm thick and the delta doped layer is 5 nm below the top of the buffer layer. The manufacture of the first delta-doped layer 18 may be carried out by any means known to those skilled in the art, including for example-interrupting the growth of the AlInAs buffer and depositing dopants.

Then, a GaInAs channel layer 6 is deposited to a thickness of 10 nm, followed by a AlInAs barrier layer 8 of thickness 15 nm. The composition of the AlInAs layer is again Al_{0.48}In_{0.52}As. The AlInAs barrier layer 8 is followed by a second delta doped layer 20. This second delta doped layer is in turn is followed by an AlInAs spacer 22 approximately 5 nm thick. An InGaAs cap layer 10 is provided over AlInAs spacer 22.

The conduction band of the channel layer is below the conduction band of the barrier and buffer layers which is achieved through the use of a higher band gap material for the barrier and buffer layers than the channel layer.

An enhancement-mode HEMT 24 is provided by etching an opening 28 through the cap layer 10 and spacer layer 22 to the barrier layer 8. An enhancement HEMT gate 12 is then deposited in the opening 28 on the barrier layer 8.

A depletion-mode HEMT 26 is provided by etching a opening 30 through the cap layer10, but not the spacer layer 22, and depositing a depletion HEMT gate 14 in the opening 30.

As will be seen in FIG. 2, the gates are formed to be so-called “T-gates” shaped as a “T” where there is no contact between the foot of the crossbar of the “T” and the cap layer 10.

It should be noted that those skilled in the art can vary many of the details above. For example, the substrate may be InP, GaAs, etc. The thickness of the buffer layer and spacer layer may be varied to achieve desired properties as will be understood by those skilled in the art. The dopants may be deposited as required .

The channel layer may be of any suitable semiconductor material—high electron mobility materials such as InGaAs are preferred though not required.

The material of the barrier layer can also be varied as required.

A second embodiment is shown in FIG. 3 which differs from the arrangement of FIG. 2 in that the second doped layer is not a delta-doped layer as in the arrangement of FIG. 2 but a thicker doped AlInAs doped layer 32. This layer means that the spacer layer 22 of the FIG. 2 arrangement is also not required. The cap layer 10 is formed directly on the AlInAs doped layer 32.

In this arrangement, the opening 28 for the enhancement mode HEMT 24 passes through the cap layer 10 and the doped layer 32, so that again the enhancement gate 12 is formed on barrier layer 8. The opening 30 for the depletion mode HEMT 26 passes through the cap layer 10 so that the gate is formed on the top of the doped layer 32.

FIG. 4 shows the band diagram of the three structures under the respective cap layer, with 0.00 μm being defined as the position under the cap layer, i.e. for a depletion mode HEMT at the interface between the gate and the underlying layer. For an enhancement mode HEMT, for which the gate is lower in the via, the HEMT starts 5 nm lower and there is no data for the range 0 to 5 nm which is in the HEMT. The enhancement mode HEMT is shown in dashed lines, the depletion mode HEMT of the second embodiment is shown in dotted line and the depletion mode HEMT of the first embodiment is shown in dotted-dashed lines.

As can be seen, the enhancement mode HEMT does not have any of the conduction band of the channel layer below the Fermi level 34 and so is an enhancement mode HEMT which needs an applied gate voltage to turn on. In contrast, both the depletion mode HEMT band diagrams do have the channel layer conduction band below the Fermi level 34 and so represent normally-on depletion mode transistors.

A benefit of these embodiments is that the depth of the gate opening 28 for the enhancement mode HEMT 24 does not have to be precisely controlled, since the pinch off voltage is almost independent of the barrier layer 8 thickness. This means that the barrier layer 8 does not need to act as a good etch stop which allows for a greatly improved series resistance and correspondingly good dynamic performance of an E-HEMT which has been very difficult if not impossible to achieve previously in ED-HEMTs.

For example, the selectivity in etch rates between InGaAs and InAlAs is about 20. This would not be sufficient for prior art arrangements but is acceptable in the present approach so no additional etch stop layer needs to be added.

A further embodiment is shown in FIG. 5. This uses a doped layer 32 as in the second embodiment, though it could be adapted to use instead a delta doped layer as in the first embodiment. In this arrangement, an opening 30 to the same depth is provided in the cap layer 10 in both the enhancement and depletion mode HEMTs 24,26. Then, a gate electrode is deposited. The material of the gate electrode is different for the enhancement and depletion mode HEMTs.

For the depletion mode HEMT, the gate material 40 is a relatively conventional Titanium/Platinum/Gold multilayer 42. For the enhancement mode FET, a diffusion layer of platinum 44 is provided on the barrier layer 20 followed by the same Titanium/Platinum/Gold multilayer 42 as for the depletion mode HEMT.

A diffusion process is carried out in the baking step, which is included in any event in the process, which diffuses platinum through the barrier layer 20 so that the platinum forms a diffused gate 46 is in contact with the doped layer . . . . The depth of the diffused gate can be controlled by varying the thickness of the diffusion layer of platinum.

In this way, the buried enhancement gate is readily manufactured since there is no need for a precisely controlled etching of the doped layer 32 in the enhancement mode FET.

In all the embodiments, the invention allows a barrier layer thickness above 5 nm, for example 10 nm or more.

The absence of the upper doped layer 16 of the prior art arrangement of FIG. 1 under the gate of the depletion mode HEMTs improves the device properties.

It is readily possible to fabricate both enhancement and depletion mode HEMTs using the same sequence of semiconductor layers.

The invention thus permits the fabrication of an ED-HEMT having good static and dynamic performance, a low series resistance and an improved output conductance. The noise performance is improved even at relatively low frequency due to a relatively low leakage current and the effective barrier height is good leading to a wide allowable gate voltage swing for the E-HEMT.

The D-HEMT gives similar performance in terms of the dynamic performances to conventional D-mode HEMTS in ED-HEMT structures but a significant improvement in maximum frequency because of the lower output conductance.

It will be understood that the invention is not limited to these embodiments and in particular different materials, layer thicknesses and doping concentrations can be used if required.

Note in this specification that where the term “over” or “above” is used no particular orientation of the transistor structure in space is intended. Further, neither of these terms are intended to imply “directly above”, so that when a first layer is said to be above a second layer there may optionally be an intermediate layer between the first and second layer.

1. A semiconductor structure including at least one enhancement mode transistor and at least one depletion mode transistor, the semiconductor structure comprising:
a substrate (2) having a first major surface;
a buffer layer (4) of semiconductor across the first major surface;
a channel layer (6) of semiconductor on the buffer layer;
a barrier layer (8) of semiconductor having a second band gap higher than the first band gap on the channel layer;
a first doped layer (18) in the buffer layer adjacent to the channel layer (6) for providing carriers to the channel layer (6); and
a second doped layer (20,32) above the barrier layer;
wherein the channel layer (6) is of semiconductor having a band gap less than the band gap of the semiconductor of the buffer layer (4) and less than the band gap of the semiconductor of the barrier layer (8);
the at least one enhancement mode transistor (24) includes a gate (12) extending through the second doped layer (20,32) and in contact with the barrier layer (8); and
the at least one depletion mode transistor (26) includes a gate (14) arranged above the second doped layer (20,32).

2. A semiconductor structure according to claim 1 wherein the second doped layer(20,32) defines an opening through the second doped layer at the enhancement mode transistor and the gate (12) of the enhancement mode transistor extends through the opening onto the barrier layer (8).

3. A semiconductor structure according to claim 1 wherein the gate (12) of the enhancement mode transistor includes a gate diffusion (40) extending through the second doped layer.

4. A semiconductor structure according to claim 3 wherein the gate diffusion is of platinum.

5. A semiconductor structure according to claim 3 wherein the gates have a T-gate structure having a contact region in contact with second barrier layer and a region of larger lateral cross section than the contact region above the contact region.

6. A semiconductor structure according to claim 1 wherein the first doped layer (18) is a delta-doped layer.

7. A semiconductor structure according to claim 1 wherein the second doped layer (20,32) is a delta-doped layer (20), further comprising a spacer layer (22) on the second doped layer, the gate opening (28) of the enhancement mode transistor (24) passing through the spacer layer (22) and the second doped layer (20).

8. A semiconductor structure according to claim 1, further comprising a cap layer (10) over the second doped layer (20,32), wherein the cap layer defines openings (28,30) for the gate (12) of the enhancement mode transistor (24) and for the gate (14) of the depletion mode transistor (26).

9. A method of manufacturing a semiconductor structure including at least one enhancement mode transistor and at least one depletion mode transistor,
providing a substrate (2) having a first major surface;
depositing a buffer layer (4) of semiconductor across the first major surface and forming a first doped layer (18) in the buffer layer (4);
depositing a channel layer (6) of semiconductor on the buffer layer (4);
depositing a barrier layer (8) of semiconductor on the channel layer (6) wherein the channel layer (6) is of semiconductor having a band gap less than the band gap of the semiconductor of the buffer layer (4) and less than the band gap of the semiconductor of the barrier layer (8);
depositing a second doped layer (20,32) above the barrier layer (8);
for the at least one enhancement mode transistor (24) depositing a gate (12) on the barrier layer (8); and
for the at least one depletion mode transistor (26) depositing a gate (14) on the second doped layer (20,32).

10. A method according to claim 9 wherein the step of forming the at least one enhancement mode transistor includes etching a gate opening (28) through the second doped layer (20,32) and depositing the gate (12) on the barrier layer in the opening (28).

11. A method according to claim 9 wherein the step of forming the at least one enhancement mode transistor includes depositing a first gate material on the second doped layer (20,32) followed by diffusing the material of the first gate material through the second doped layer (20,32) to the barrier layer (8).

12. A method according to claim 11 wherein the step of forming the gate electrodes includes depositing a diffusion gate material that diffuses through the second doped layer on the second doped layer of the enhancement mode transistor but not the depletion mode transistor;
depositing gate material on the diffusion gate material of the enhancement mode transistor and on the second doped layer (20,32) of the depletion mode transistor; and
heating the structure to diffuse the diffusion gate material through the second doped layer (20,32) to the barrier layer (8).

13. A method according to claim 12 wherein the diffusion gate material is platinum.

14. A method of manufacturing a semiconductor structure according to claim 9 including the step of delta-doping the buffer layer (4) to deposit the first doped layer (18).

15. A method of manufacturing a semiconductor structure according to claim 9 wherein the step of depositing a second doped layer above the barrier layer deposits a delta-doped layer (20), the method further comprising depositing a spacer layer (22) on the delta-doped layer (20).

16. A method of manufacturing a semiconductor structure according to claim 9, further comprising:
depositing a cap layer (10) above the second doped layer (20,32); and
defining openings (28,30) in the cap layer for the gate (12) of the or each enhancement mode transistor (24) and for the gate (14) of the or each depletion mode transistor (26).

17. A method according to claim 16 wherein the gate electrodes are formed to be T-shaped electrodes in contact with the second doped layer but not the cap.
